(19) United States
(12) Patent Application Publication
(10) Pub. No.: US 2023/0099081 A1
(43) Pub. Date: Mar. 30, 2023

(54) METHOD FOR CONTROLLING A POWER GRID AND GRID CONTROL ARRANGEMENT

(71) Applicant: Siemens Aktiengesellschaft, München (DE)

(72) Inventors: Volker Henn, Erlangen (DE); Andreas Litzinger, Fürth (DE); Christian Romeis, Erlangen (DE)

(21) Appl. No.: 17/953,863

(22) Filed: Sep. 27, 2022

(30) Foreign Application Priority Data
Sep. 29, 2021 (EP) 21199915.6

(51) Int. Cl. H02J 13/00; G06F 1/26

(52) U.S. Cl. CPC H02J 13/00006; G06F 1/26; H02J 13/00002

(57) ABSTRACT

A method for controlling a power grid includes using a communication device to receive first data messages with first phasor measurement data from a first phasor measurement unit. A reference device is used to determine a deviation between the first phasor measurement data and reference data. The first phasor measurement data are recognized as plausible when the deviation lies below a previously defined upper threshold value and/or above a previously defined lower threshold value. A corresponding grid control arrangement is also provided.

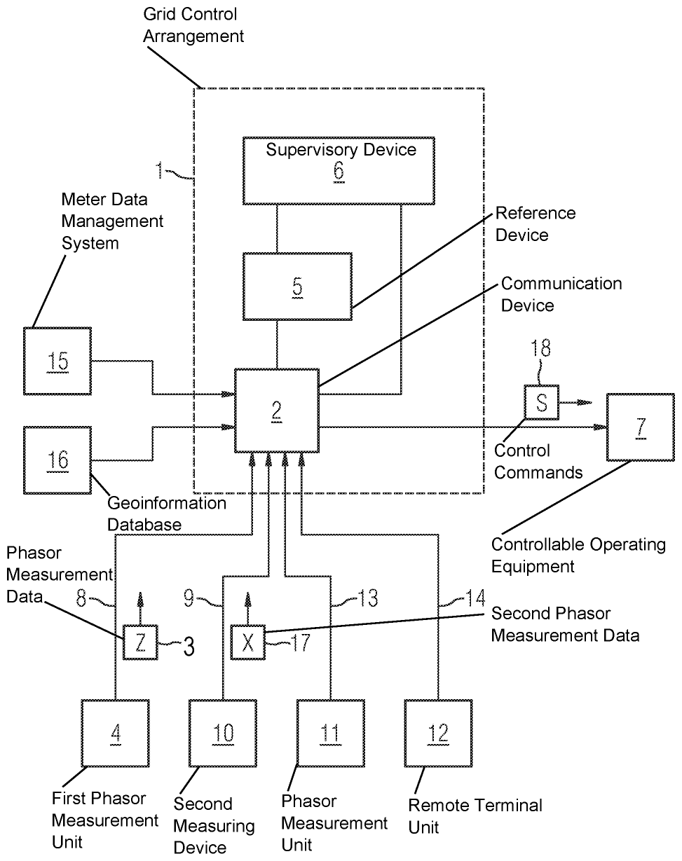

### CROSS-REFERENCE TO RELATED APPLICATION

This application claims the priority, under 35 U.S.C. § 119, of European Patent Application EP21199915.6, filed Sep. 29, 2021; the prior application is herewith incorporated by reference in its entirety.

### FIELD AND BACKGROUND OF THE INVENTION

The present invention relates to a method for controlling a power grid, which includes receiving first data messages with first phasor measurement data from a first phasor measurement unit by using a communication device. The invention also relates to a grid control arrangement, including a communication device configured to receive first data messages with first phasor measurement data from a first phasor measurement unit.

The product brochure “SIGUARD PDP Grid Monitoring using Synchrophasors”, Siemens AG 2021, discloses software for so-called “Wide Area Monitoring Protection and Control (WAMPAC)”, i.e. wide area monitoring and supervision of a power grid. This involves evaluating measurement data from so-called “Phasor Measurement Units” (PMUs), which with high temporal resolution supply measurement data about voltage magnitudes and voltage angles, current magnitudes and current angles and also grid frequency and rate of change of grid frequency at the installation location of the respective PMU. PMUs are used e.g. in a transformer substation or at a switchgear apparatus and are connected to the transformers, lines and/or busbars. Measurement data are communicated by way of Internet-Protocol (IP) based data communication to the Software SIGUARD PDP, installed, e.g., on a server computer device in a grid control center of a grid operator for the power grid. On the basis of the measurement data, the software recognizes, e.g. whether the monitored electrical power grid has a stable grid frequency, a stable voltage, a stable transmission and no power oscillations. Furthermore, protective devices in the power grid can be optimized on the basis of predicted disturbances in order to avoid outages.

WAMPAC systems use standardized protocols such as e.g. IEEE C37.118, IEC 60870-6-104, IEC 61850, etc., but require a great manual set-up effort. It is only in that way that interoperability can be ensured if many different devices communicate with the central evaluation server.

The measurement data arriving at the WAMPAC system are generally not checked with regard to manipulations. Causes of falsified or corrupted measurement data may be e.g.: GPS spoofing (feigning an incorrect “Global Positioning System” (GPS) signal by using a strong local radio transmitter in order to obtain incorrect location and/or time indications), measurement errors of the measuring instrument, erroneously read state values of a switchgear apparatus, damaged connectors (e.g. AUX) or cables, errors in the time synchronization of the PMUs, cyber-attacks and other manipulations. Therefore, it is possible, in principle, for falsified or corrupted measurement data to be used for the further evaluation in the WAMPAC system, which can lead to physically incorrect results and thus also to non-targeted supervisory interventions in the grid management.

In the worst case, there is threat of an outage of a portion or the entirety of the monitored power grid.

### SUMMARY OF THE INVENTION

It is accordingly an object of the invention to provide a method for controlling a power grid and a grid control arrangement, which overcome the hereinafore-mentioned disadvantages of the heretofore-known methods and arrangements of this general type and which, proceeding from known software-implemented methods for controlling a power grid, ensure particularly high availability and security for the power grid.

With the foregoing and other objects in view there is provided, in accordance with the invention, a method for controlling a power grid, comprising the steps of:
receiving first data messages with first phasor measurement data from a first phasor measurement unit by using a communication device; and
determining a deviation between the first phasor measurement data and reference data by using a reference device, wherein for the case where the deviation lies below a previously defined upper threshold value and/or above a previously defined lower threshold value, the first phasor measurement data are recognized as plausible.

The basic concept of the invention is to verify the arriving measurement data and switching states by using a second reference system. This may be e.g. another data source such as a “Meter Data Management” (MDM) system for acquiring and evaluating smart meter data, a digital twin of the power grid, a different simulation for the measurement data or a state estimation for the power grid from grid control center software. Furthermore, combinations of measurement data originating from different measuring devices at the same location and digital twins of measuring devices per se can be used for checking purposes.

A power grid within the meaning of the invention is e.g. an electrical power distribution or supply grid that supplies e.g. individual regions or towns/cities. It can have different voltage levels, e.g. a transmission level with high voltage of more than 52 kV rated voltage, a medium-voltage level with a rated voltage of between 1 kV and 52 kV and also a low-voltage level with a rated voltage of less than 1 kV.

The term control denotes the controlling of controllable operating equipment such as switching devices, gas-insulated switching devices, tap switches of transformers, capacitor banks, grid controllers, etc., by using control commands communicated by way of data communication. Furthermore, it can e.g. also encompass the controlling of generators of electrical power or consumers of electrical power in order to control their respective infeed or drawing of electrical power into/from the power grid. In this case, it is also possible to evaluate topology information about the arrangement and interconnection of the power grid, i.e. also taking account of present switching states of switching devices.

Data messages are e.g. digital messages, i.e. bit sequences. The communication device can establish data communication connections by using a wide variety of communication channels, e.g.: “Powerline Communication” connections over a power line, radio connections according to the 2G,3G,4G,5G or long-range radio standard or optical connections using optical waveguides. Furthermore, conventional copper cables of data transmission technology can be used.

The communication device, the supervisory device and the reference device are e.g. hardware components and/or software components disposed for example in a field device or a protective device on site in a transformer substation. This affords advantages over a remotely offered solution, e.g. by way of a cloud infrastructure, because the PMUs supply measurement data with a temporal resolution in the ms range (e.g. every 20 ms) which for wide area control affords the significant advantage of being able to already recognize disturbances and initiate countermeasures in fractions of a second. Offering these functionalities (supervisory device, reference device) as software components on a remote server computer arrangement or in a cloud can be used advantageously, however, if very short latencies for the data communication can be ensured (less than 100 ms).

Within the meaning of the invention, a field device, a protective device or a server computer arrangement includes data processor resources such as e.g. “Central Processing Units” (CPUs) and/or “Graphics Processing Units” (GPUs) and also data storage resources such as e.g. “Solid state disks” (SSDs) or magnetic hard disk drives (HDDs).

Phasor measurement data include e.g. a voltage value, a current intensity value, a phase angle, a time stamp and optionally a geographical position.

A deviation within the meaning of the invention is e.g. a positive or negative numerical value that results when e.g. a reference value for the voltage is subtracted from a voltage value measured by the PMU. If the voltage measured by the PMU is e.g. 395 V and the reference value is 380 V, then the deviation is A=395 V−380 V=15 V, which corresponds to a percentage deviation of Ap=15 V/395 V=3.8%. This procedure can likewise be adopted for the current intensity and the phase angle. It goes without saying that the absolute values of the deviation can also be used besides a percentage deviation.

The upper and lower threshold values define a permissible interval of the deviation between measurement data and reference data. For each measurement variable (voltage, current intensity, phase angle), for example, it is possible to define a dedicated absolute or percentage upper and lower threshold value or else a percentage value that applies to all the measurement variables. By way of example, 410 V or a percentage deviation of 3% to 5%, preferably 5% to 10% can be defined as a previously defined upper threshold value. By way of example, if 5% is defined as upper threshold value and −6% is defined as lower threshold value, then the initially calculated deviation of the voltage of 3.8% is plausible. Accordingly, the measured value of 395 V can continue to be used to carry out the wide area control.

In order to define permissible deviations, it should be borne in mind that PMUs typically have very accurate measuring instruments and, in a manner governed by their configuration, have tolerances of e.g. 0.1% to 0.5%, while RTUs typically have tolerances of e.g. 1% to 3%. Due to the comparatively high design-governed measurement inaccuracy of RTUs, it is therefore expedient to choose the threshold values so as to encompass a range for the measurement accuracy of the measuring systems.

By way of example, it is also possible for only a deviation in terms of magnitude to be calculated, which is permissible e.g. within +/−5% of the measured value.

A significant advantage of the invention is that the trustworthiness of the incoming measurement data for the WAMPAC system is improved, such that improved supervision of the power grid is consequently achieved as well in order to be able to counteract disturbances rapidly with expedient countermeasures. Decisions or actions (e.g. transmitting a control command in order to open a switch) which influence the power grid in critical situations become more reliable and more resilient vis-à-vis corrupted data than was the case in previous systems.

In one preferred embodiment of the method according to the invention, by using a supervisory device, the first phasor measurement data recognized as plausible are taken into account for recognition of a critical system state and countermeasures are determined. This is an advantage because the PMU measurement data checked for plausibility are used for wide area control.

In a further preferred embodiment of the method according to the invention, control commands for protective devices and/or controllable operating equipment are defined on the basis of the countermeasures by using the supervisory device, and second data messages with the control commands are transmitted to the protective devices and/or the controllable operating equipment by using the communication device. This is an advantage because the countermeasures enable very rapid intervention in the operational management of the power grid in order to eliminate disturbances. By way of example, one countermeasure may be opening a switch (i.e. load shedding).

In a further preferred embodiment of the method according to the invention, the reference data are determined on the basis of a digital twin of the power grid by using a reference device. Within the meaning of the invention, a digital twin of the real system is software which can simulate the real power grid. The simulation can be used to estimate reference values for measurement data at all measurement points in the power grid. This is an advantage because the received measurement data can be verified simply and accurately in this way.

In a further preferred embodiment of the method according to the invention, the reference data are determined with the aid of a meter data management system by using the reference device. A meter data management system receives from so-called smart meters every 15 minutes, for example, power consumption values and also voltage and current intensity values at the measurement locations, which are typically installed at the grid connection point of buildings. This is an advantage because the received measurement data can be verified simply and accurately in this way.

In a further preferred embodiment of the method according to the invention, the reference data are determined on the basis of a state estimation for the power grid by using the reference device. A state estimation is carried out for example by control center software on a server computer arrangement in the grid control center of the operator of the power grid. Input variables are, inter alia, measurement data indicated in terms of magnitude for voltage and current intensity, which are supplied by field devices such as so-called “Remote Terminal Units” (RTU). These measurement data of the RTUs accordingly do not contain phase information, i.e. are not phasor measurement data like the data supplied by the PMUs. If a state estimation is present, phase angles at the measurement location of the first phasor measurement unit can be deduced from the state estimation and a comparison can be carried out. The state estimation can be received for example by way of a data message by using the communication device.

In a further preferred embodiment of the method according to the invention, the reference data are determined on the basis of measurement data, originating from a second measuring device by using the reference device. This is an advantage because a situation can be exploited in which the second measuring device and the first phasor measurement unit supply comparable data.

In a further preferred embodiment of the method according to the invention, a measuring device which is assigned to the same busbar as the first phasor measurement unit is used for the second measuring device, and the assignment to the same busbar is checked by using the reference device taking account of topological information about the power grid. By way of example, a busbar includes 3 to 4 connected lines for which there is available topological information that the corresponding circuit breakers connecting the lines to the busbar are closed. In such a case, often there is situated on the busbar an installed PMU and optionally on one or more lines a second measuring device, which can measure e.g. voltage and current intensity in terms of magnitude. Optionally, a further busbar is also attached and galvanically connected to a further PMU. In these cases, all the measuring devices should supply comparable measurement data. The topological information can be obtained from a grid control center or a protective device, for example.

In one development, an average value can be formed from the measurement data supplied by the first phasor measurement unit and at least one further second measuring device, that average value being taken into account for the wide area control. This can be done if the phasor measurement data measured by the first phasor measurement unit were recognized as plausible. A weighted average can also be calculated, in which case, for example, weighting is effected according to the type of measuring device with regard to the design-governed measurement accuracy explained in the introduction. Measurement data of an RTU are thus weighted more highly than measurement data of a PMU. Furthermore, weighting can be effected according to the operating period of the measuring instruments used, and that is to say that e.g. a measuring device that is 10 years old is given a smaller weighting than a measuring device that has been in operation for less than 5 years.

In a further preferred embodiment of the method according to the invention, a second phasor measurement unit used at a different end of a transmission line than the first phasor measurement unit is used for the second measuring device, wherein an electrical model of the transmission line is taken into account by using the reference device. If the impedance of the line is known in the context of the electrical model, then on the basis of the measurement data of the second phasor measurement unit, besides voltage and current intensity, it is also possible to calculate what phase angle should be expected at the measurement point of the first phasor measurement unit.

In a further preferred embodiment of the method according to the invention, first data messages including a time stamp and/or geographical coordinates are received by using the communication device, and a deviation is in each case determined between the time stamp and/or the geographical coordinates of the first phasor measurement unit and reference data for the time stamp and/or the geographical coordinates by using the reference device. This variant is particularly advantageous for recognizing a malicious manipulation by a third party. By way of example, an attacker may aim to disrupt the acquisition of time stamp and/or geographical coordinates, determined by using GPS, at the installation location of the first phasor measurement unit. The attacker may use so-called GPS spoofing, for example, which involves a strong radio transmitter locally emitting a falsified GPS signal that is much stronger than the genuine GPS signal received from satellites. In this way, the first phasor measurement unit may be led to believe e.g. that the installation location lies e.g. in a different time zone. Accordingly, the further processing of the transmitted phasor measurement data with an incorrect time stamp would lead to incorrect estimations in the context of the wide area control.

In a further preferred embodiment of the method according to the invention, the reference data for the time stamp and/or the geographical coordinates are determined by using the reference device taking account of a time delay in the time stamp. This involves checking whether the propagation time of the radio signals from the satellites is plausible in view of the communicated geographical position and the time stamp.

Furthermore, manipulations or faults can easily be recognized if the time stamps of measurement data supplied by a PMU are not continuous, but rather have jumps of e.g. a few seconds or more.

In a further preferred embodiment of the method according to the invention, the reference data for the time stamp and/or the geographical coordinates are determined by using the reference device taking account of a previously known geographical position of the first phasor measurement unit. This presupposes that a geoinformation system is provided, for example, in which e.g. the GPS coordinates—acquired during device installation—of phasor measurement units are acquired.

Proceeding from known grid control arrangements, the problem addressed by the invention is furthermore that of specifying a grid control arrangement for controlling a power grid which ensures particularly high availability and security for the power grid.

With the objects of the invention in view, there is also provided a grid control arrangement for a power grid, comprising:
a communication device configured to receive first data messages with first phasor measurement data from a first phasor measurement unit; and
a reference device configured to determine a deviation between the first phasor measurement data and reference data, wherein for the case where the deviation lies below a previously defined upper threshold value and/or above a previously defined lower threshold value, the first phasor measurement data are recognized as plausible.

Preferred embodiments are specified in the dependent claims. The same advantages as initially explained for the method according to the invention are analogously afforded for the grid control arrangement according to the invention and its embodiment.

In one preferred embodiment of the grid control arrangement according to the invention, the supervisory device is configured to define control commands for protective devices and/or controllable operating equipment on the basis of the countermeasures, and the communication device is configured to transmit second data messages with the control commands to the protective devices and/or the controllable operating equipment.

Other features which are considered as characteristic for the invention are set forth in the appended claims.

Although the invention is illustrated and described herein as embodied in a method for controlling a power grid and a grid control arrangement, it is nevertheless not intended to be limited to the details shown, since various modifications and structural changes may be made therein without departing from the spirit of the invention and within the scope and range of equivalents of the claims.

The construction and method of operation of the invention, however, together with additional objects and advantages thereof will be best understood from the following description of specific embodiments when read in connection with the accompanying drawings.

### BRIEF DESCRIPTION OF THE FIGURE

The FIGURE of the drawing is a block diagram showing one preferred exemplary embodiment of the invention.

### DETAILED DESCRIPTION OF THE INVENTION

Referring now in detail to the single FIGURE of the drawing, there is seen a grid control arrangement 1 for a power grid (not illustrated), which includes a communication device 2 and a reference device 5 as well as a supervisory device 6.

A first phasor measurement unit 4 uses a data communication connection 8 to transmit first phasor measurement data z with a first data message 3, which is received by the communication device 2. A second measuring device 10 is embodied as a second phasor measurement unit, which transmits second phasor measurement data x with a second data message 17 by using a data communication connection 9. Both phasor measurement units 4, 10 are for example connected to the same busbar or connected over a line. In the latter case, the reference device 5 can calculate what phasor measurement data should be expected by taking an electrical model of the line into account.

The reference device 5 serves to determine a deviation between the first phasor measurement data z and reference data, in this case the second phasor measurement data x. In the case where the deviation lies below a previously defined upper threshold value and/or above a previously defined lower threshold value, the first phasor measurement data are recognized as plausible by the reference device 5 and forwarded to the supervisory device 6.

The supervisory device 6 can take the first phasor measurement data z recognized as plausible into account for recognition of a critical system state and can determine countermeasures, which can be transmitted by the communication device 2 with the aid of a data message 18 with control commands s to controllable operating equipment 7 such as a circuit breaker, for example, and can be implemented. The supervisory device 6 can additionally have a “Supervisory Control and Data Acquisition” (SCADA) functionality and create a dedicated state estimation for the electrical power grid. Moreover, a functionality for disturbance recognition on the basis of the state estimation can be provided.

Another possibility for a plausibility check exists if different measuring systems such as a PMU 11, which supplies phasor measurement data, and an RTU 12, which supplies measurement values in terms of magnitude for voltage and current intensity, are used at the same location. In such a case, by using the RTU measurement data, the supervisory device can create a state estimation from which the expectable phasor measurement data of the PMU can be deduced. The reference data thus obtained can then be compared with the phasor measurement data of the PMU 11 by the reference device 5, as explained initially.

By way of example, a meter data management system 15 and a geoinformation database 16, in which geographical positions of the PMUs 4,10,11 and of the RTU 12 are stored, can serve as further data sources for determining reference data.

1. A method for controlling a power grid, the method comprising:
using a communication device to receive first data messages with first phasor measurement data from a first phasor measurement unit;
using a reference device to determine a deviation between the first phasor measurement data and reference data; and
recognizing the first phasor measurement data as plausible when the deviation lies at least one of below a previously defined upper threshold value or above a previously defined lower threshold value.

2. The method according to claim 1, which further comprises using a supervisory device to take the first phasor measurement data recognized as plausible into account for recognition of a critical system state and determining countermeasures.

3. The method according to claim 2, which further comprises:
using the supervisory device to define at least one of control commands for protective devices or controllable operating equipment based on the countermeasures; and
using the communication device to transmit second data messages with the control commands to at least one of the protective devices or the controllable operating equipment.

4. The method according to claim 1, which further comprises using the reference device to determine the reference data based on a digital twin of the power grid.

5. The method according to claim 1, which further comprises using a meter data management system to aid the reference device in determining the reference data.

6. The method according to claim 1, which further comprises using the reference device to determine the reference data based on a state estimation for the power grid.

7. The method according to claim 1, which further comprises using the reference device to determine the reference data based on measurement data originating from a measuring device.

8. The method according to claim 7, which further comprises:
assigning both the first phasor measurement unit and a measuring device to one busbar;
using the measuring device as a second measuring device; and
checking the assignment to the one busbar by using the reference device and taking topological information about the power grid into account.

9. The method according to claim 8, which further comprises:
locating the first phasor measurement unit and a second phasor measurement unit at different ends of a transmission line;
using the second phasor measurement unit for the second measuring device; and
using the reference device to take an electrical model of the transmission line into account.

10. The method according to claim 1, which further comprises:
using the communication device to receive first data messages including at least one of a time stamp or geographical coordinates; and
using the reference device to determine each respective deviation between at least one of the time stamp or the geographical coordinates of the first phasor measurement unit and reference data for at least one of the time stamp or the geographical coordinates.

11. The method according to claim 10, which further comprises determining the reference data for at least one of the time stamp or the geographical coordinates by using the reference device and taking a time delay in the time stamp into account.

12. The method according to claim 10, which further comprises determining the reference data for at least one of the time stamp or the geographical coordinates by using the reference device and taking a previously-known geographical position of the first phasor measurement unit into account.

13. A grid control arrangement for a power grid, the grid control arrangement comprising:
a first phasor measurement unit;
a communication device configured to receive first data messages with first phasor measurement data from said first phasor measurement unit; and
a reference device configured to determine a deviation between the first phasor measurement data and reference data;
the first phasor measurement data being recognized as plausible when the deviation lies at least one of below a previously defined upper threshold value or above a previously defined lower threshold value.

14. The grid control arrangement according to claim 13, which further comprises a supervisory device configured to take the first phasor measurement data recognized as plausible into account for recognition of a critical system state and to determine countermeasures.

15. The grid control arrangement according to claim 13, wherein said reference device is configured to determine the reference data based on a digital twin of the power grid.
